(19) United States
(12) Patent Application Publication
(10) Pub. No.: US 2005/0214971 A1
(43) Pub. Date: Sep. 29, 2005

(54) BUMPING PROCESS, BUMP STRUCTURE, PACKAGING PROCESS AND PACKAGE STRUCTURE

(76) Inventor: Ching-Fu Hung, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,158

(22) Filed: Mar. 23, 2005

(30) Foreign Application Priority Data
Mar. 26, 2004 (TW) 93108238

(51) Int. Cl. H01L 21/44

(52) U.S. Cl. 438/106

(57) ABSTRACT

A bumping process, a bump structure, a packaging process and a package structure are described. The bump structure comprises a first solder portion, a second solder portion and a conductive layer. The second solder portion is disposed on the first solder portion and the conductive layer is disposed between the first solder portion and the second solder portion. The bumping process produces a bump structure having a greater height. The bumping process can also be applied in a package process to form a package structure having a highly reliable connection between a chip and a packaging substrate.

### CROSS-REFERENCE TO RELATED APPLICATION

This application claims the priority benefit of Taiwan application serial no. 93108238, filed on Mar. 26, 2004.

### BACKGROUND OF THE INVENTION

1. Field of the Invention

The present invention relates to a bumping process, a bump structure, a packaging process and a package structure. More particularly, the present invention relates to a bumping process, a bump structure, a packaging process and a package structure capable of increasing bump height so that a highly reliable connection between a chip and a packaging substrate is formed.

2. Description of Related Art

Since communication has become increasingly important in the modern world, the market for multi-media systems continues to expand. To meet the demands of multi- media users, many types of integrated circuit packages have already incorporated digital, networking, local area communication and customization functions. In other words, the processing speed, functions, and the level of integration must be increased while the weight and the cost of the product must be reduced. One convenient method of increasing power and capacity of integrated circuit packages is to miniaturize the devices and increase the density of circuits. Ball grid array (BGA) packages, chip scale packages (CSP), flip chip (F/C) packages and multi-chip modules (MCM) are just some of the high density integrated circuit packages now commonly in use. The density of an integrated circuit package is often gauged because a higher packing density means more pins are accommodated per unit package area. Because shortening the average length of distribution lines can surely increase the signal transmission speed of a high-density integrated circuit package, bumps have become an indispensable means of connecting a chip and a package substrate inside a high density packages.

FIGS. 1A through 1F are schematic cross-sectional views showing the steps in a conventional process for forming bump structures. First, as shown in FIG. 1A, a wafer 100 is provided. The wafer 100 has a plurality of bonding pads 102 disposed on an upper surface. Furthermore, a passivation layer 106 covers the upper surface of the wafer 100. The passivation layer 106 has openings that expose the bonding pads 102. The wafer further has an under-bump-metallic (UBM) layer 104 disposed on the exposed surface of the bonding pads 102 and a portion of the passivation layer 106 around the bonding pads 102.

As shown in FIG. 1B, a photoresist layer 108 is formed over the wafer 100. Thereafter, as shown in FIG. 1C, a plurality of openings 108a corresponding bonding pads 102 are formed in the photoresist layer 108 via photolithography, etching and development process. Through the openings 108a, the under-bump-metallic (UBM) layers 104 are exposed.

As shown in FIG. 1D, solder material is filled into the openings 108a by a stencil process to form a solder post 110 over each UBM layer 104. Thereafter, as shown in FIG. 1E, the photoresist layer 108 is removed to expose the solder posts 110.

As shown in FIG. 1F, a reflow process is carried out by heating the solder posts 110 to the melting point thereof so that a spherical-like body is formed due to inter-molecular cohesion of the bulk material. When the solder posts 110 solidify again upon cooling, a ball-shaped bump 110a is formed on each UBM layer 104.

FIG. 2 is a side view of a conventional package comprising a chip and a package substrate joined together through bumps. As shown in FIGS. 1F and 2, the wafer 100 is sawed to form a plurality of chips 100a after the bumping process is completed. The chip 100a is electrically connected to the contacts 152 of the package substrate 150 through the bumps 110a by a flip-chip attached method. Finally, an underfill 140 is filled into the space between the chip 100a and the package substrate 150 to protect the exposed portion of the bumps 110a.

It should be noted that a thermal strain would be created due to a mismatch of the thermal expansion coefficient between the package substrate and the chip. In other words, the bumps have to endure some of the shear stress. When the bumps are subjected to a shear stress that exceed its permissible limit, the bumps might crack leading to an open circuit in the electrical connection between the chip and the package substrate. Furthermore, because the sidewalls of the openings in the photoresist layer for forming the bumps are almost perpendicular to the surface of the wafer, the amount of solder material inside the opening is quite limited. Because the average height of the bumps is low, shearing stress between the chip and the package substrate due to thermal stress can easily damage the bumps leading to a package failure. Hence, one way of preventing the shear stress from damaging the bumps and causing reliability problems is to increase the vertical height of the bumps above the wafer surface.

### SUMMARY OF THE INVENTION

The present invention is directed to a bumping process, a bump structure, a packaging process and a package structure for increasing the average height of the bumps so that the electrical connection between a chip and a package substrate is more reliable.

According to an embodiment of the present invention, the invention provides a bumping process for forming a plurality of bumps on a plurality of contacts of a wafer or a package substrate. First, a first solder portion is formed on each contact. Then, a conductive layer is formed on each first solder portion. Furthermore, the bumping process further comprising a step of forming a metallic layer over the wafer, wherein the metallic layer at least covers the contacts.

Each conductive layer is formed, for example, by forming a first wetting layer over the first solder portions, forming a barrier layer over the first wetting layer and forming a second wetting layer over the barrier layer. Furthermore, the first wetting layer and the second wetting layer is fabricated using copper and the barrier layer is fabricated using nickel-vanadium alloy, for example.

In addition, a patterned photoresist layer is formed over the wafer before forming the first solder portions. The patterned photoresist layer has a plurality of openings that expose the metallic layer above the bonding pads. Furthermore, a plurality of second solder portions are formed over the conductive layer after forming the conductive layer. An electroplating process or a printing process, for example, is used to form the second solder portions.

After forming the first solder portions, the conductive layer as well as the second solder portions and removing the patterned photoresist layer, a reflow process is carried out to melt the first solder portions and the second solder portions. Hence, a bump structure is formed over each bonding pad.

In the aforementioned embodiment, a wafer having a plurality of bonding pads and a passivation layer thereon is provided and then a metallic layer is formed over the wafer. However, anyone familiar with the packaging techniques may choose a package substrate having a plurality of contacts thereon instead of performing the aforesaid steps. After that, a plurality of first solder portions are formed over the package substrate.

The present invention is also directed to a bump structure. The bump structure comprises a first solder portion, a second solder portion and a conductive layer. The second solder portion is disposed over the first solder portion and the conductive layer is disposed between the first solder portion and the second solder portion. The first solder portion and the second solder portion have a cylindrical shape or a spherical shape. Furthermore, the first solder portion and the second solder portion can be fabricated using tin-lead alloy, tin-silver alloy or tin-silver-copper alloy, for example. There is no restriction on whether the first solder portion and the second solder portion should be fabricated from different materials or an identical material.

In addition, the conductive layer comprises a first wetting layer, a barrier layer and a second wetting layer. The first wetting layer is disposed on the first solder portion, the barrier layer is disposed on the first wetting layer and the second wetting layer is disposed on the barrier layer. The first wetting layer and the second wetting layer are fabricated using copper and the barrier layer is fabricated using nickel-vanadium alloy, for example.

According to an embodiment of the present invention, the present invention provides a packaging process comprising the following steps. First, a wafer having a plurality of bonding pads and a passivation layer is provided, wherein the passivation layer protects the wafer and exposes the bonding pads. A metallic layer is formed over the wafer to cover at least the bonding pads. An electroplating operation is carried out to form a plurality of first solder portions disposed on the metallic layer above each bonding pad. Thereafter, a plurality of conductive layers are formed on each first solder portion. An electroplating or printing process is carried out to form a plurality of second solder portions disposed on the metallic layer above the bonding pads. The wafer is sawed to form a plurality of chips. A package substrate having a plurality of contacts thereon is provided. A reflow process is carried out to join the second solder portions on the chip with the contacts on the surface of the package substrate.

The step of forming the conductive layers comprises forming a first wetting layer over the first solder portions, forming a barrier layer over the first wetting layer and then forming a second wetting layer over the barrier layer. The first wetting layer and the second wetting layer are fabricated using copper and the barrier layer is fabricated using nickel-vanadium alloy, for example.

In addition, a patterned photoresist layer is formed over the wafer before forming the first solder portions. The patterned photoresist layer has a plurality of openings that expose the metallic layer above the bonding pads.

The present invention is also directed to a package structure comprising a package substrate, at least a chip and a plurality of bump structures. The package substrate has a plurality of contacts formed thereon. The chip is disposed over the package substrate. The chip has a plurality of bonding pads and a passivation layer protecting the chip but exposing the bonding pads. Furthermore, each bonding pad has a under-bump-metallic layer disposed thereon. The bump structures having a configuration similar to the aforesaid bump structure are disposed between the contacts of the package substrate and the under-bump-metallic layer of the chip.

In addition, the package substrate has a solder mask layer disposed on the surface just outside the contacts. Furthermore, the conductive layer in some of the bump structures are raised to a first height level while the conductive layer in other bump structures are raised to a second height level.

In brief, the bumping process, the bump structure, the packaging process and the package structure of the present invention all involve stacking up a pair of bumps to form a bump structure to increase the height of the bump structure significantly. Therefore, the bump structures can be subjected to a higher thermal shear stress without failure after the chip and the package substrate are joined together to form a chip package. In other words, the electrical connections between the chip and the package substrate are more reliable when the bump structure has a greater height.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1F are schematic cross-sectional views showing the steps of a conventional process of forming bump structures.

FIG. 2 is a side view of a conventional package comprising a chip and a package substrate joined together through bumps.

FIGS. 3A through 3F are schematic cross-sectional views showing the steps of fabricating a bump structure according to one embodiment of the present invention.

FIGS. 4A through 4E are schematic cross-sectional views showing the steps of fabricating a package structure according to one embodiment of the present invention.

FIGS. 5A through 5F are schematic cross-sectional views showing the steps of fabricating a package structure according to another embodiment of the present invention.

FIG. 6 is a schematic cross-sectional view of a package structure according to one embodiment of the present invention.

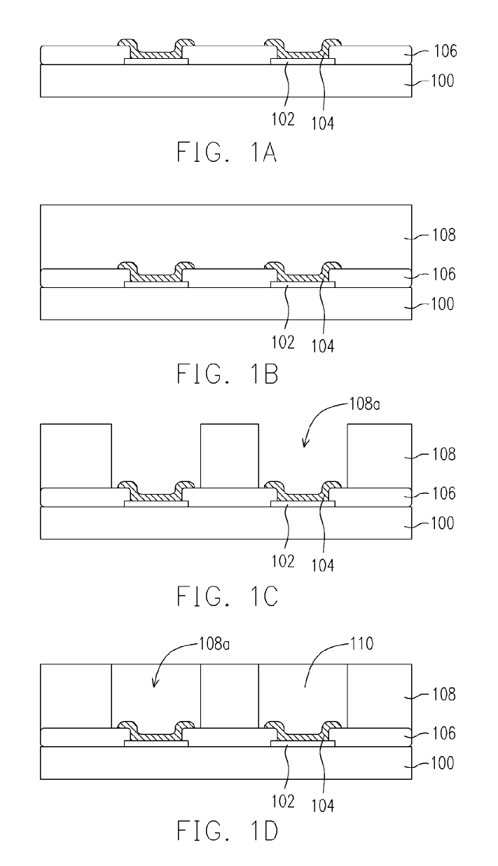

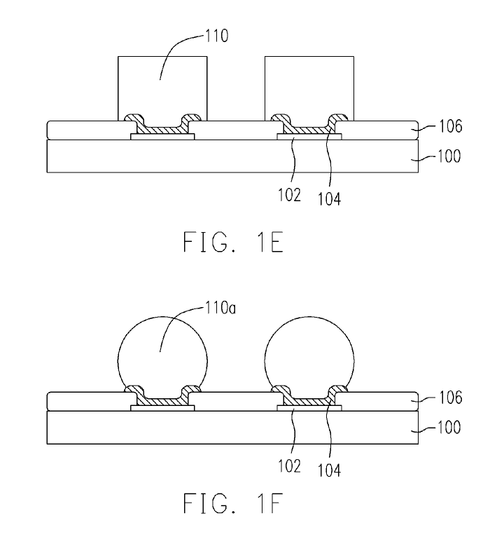

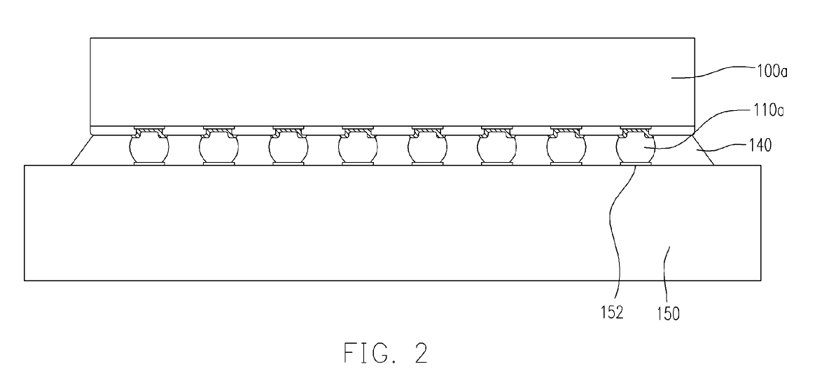

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

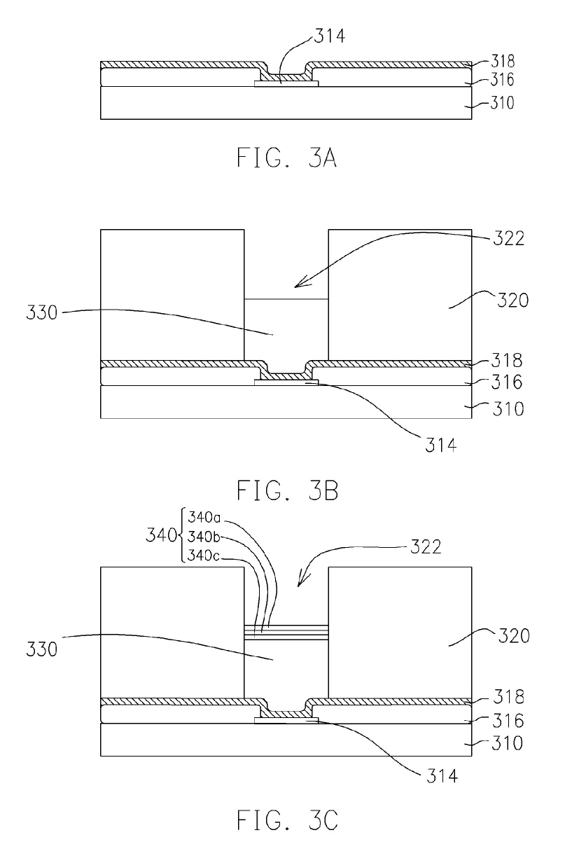

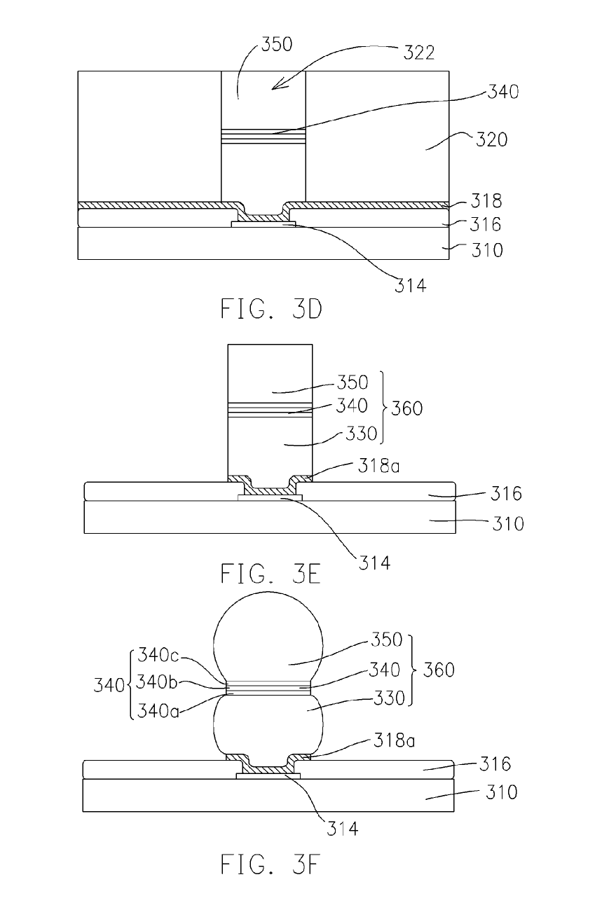

FIGS. 3A through 3F are schematic cross-sectional views showing the steps of fabricating a bump structure according to one embodiment of the present invention. First, as shown in FIG. 3A, a wafer 310 is provided. The wafer 310 has a plurality of bonding pads 314 and a passivation layer 316, wherein the passivation layer 316 protects the wafer 310 and exposes the bonding pads 314. Thereafter, a metallic layer 318 is formed over the wafer 318. The metallic layer 318 covers the bonding pads 314 and the passivation layer 316, for example.

The metallic layer 318 is formed in a sputtering or evaporation process, for example. The metallic layer 318 is a three-layer stacked structure comprising an adhesion layer, a barrier layer and a wetting layer. The adhesion layer increases the bonding strength between the metallic layer 318 and the bonding pad 314, the barrier layer prevents any mobile ions from diffusing through the metallic layer 318 into the wafer 310. The wetting layer enhances the bonding strength of the metallic layer 318 with a subsequently deposited solder material. The metallic layer 318 is fabricated using titanium/nickel-vanadium alloy/copper, aluminum/nickel-vanadium alloy/copper or other combinations of materials having the aforementioned properties.

As shown in FIG. 3B, a patterned photoresist layer 320 is formed over the wafer 310 to cover the metallic layer. In the present embodiment, the photoresist layer 320 is formed by performing a dry film attaching process or spin-coating a liquid photoresist material, for example. The patterned photoresist layer 320 has a plurality of openings 322 located above the bonding pads 314 to expose the metallic layer 318. Thereafter, an electroplating process is carried out to fill solder material into each opening 322 to form a plurality of first solder portions 330. The first solder portion 330 fills the openings 322 only partially.

As shown in FIG. 3C, a sputtering, electroplating or evaporation process is performed to form a conductive layer 340 over each first solder portion 330. The conductive layer 340 is formed, for example, by forming a first wetting layer 340a over the first solder portion 330. After that, a barrier layer 340b is formed over the first wetting layer 340a. Finally, a second wetting layer 340c is formed over the barrier layer 340b.

As shown in FIGS. 3D and 3E, an electroplating or a printing process is performed to fill the remaining space of each opening 322 with a solder material so that a plurality of second solder portions 350 are formed over the conductive layer 340. After removing the patterned photoresist layer 320, the exposed metallic layer 318 is also removed to form a plurality of under-bump-metallic layers 318a. Obviously, a printing process or some other process can be used to fabricate the first solder portions 330. If a printing method is deployed to form the first solder portions 330, the metallic layer 318 can be patterned to form a plurality of under-bump-metallic layers 318a prior to forming the patterned photoresist layer 320. Furthermore, the volume of the first solder portion 330 can be identical to or different from the second solder portion 350 so that the conductive layers 340 can be disposed at different height levels.

As shown in FIGS. 3E and 3F, a reflow process of the first solder portion 330 and the second solder portion 350 is performed to form a bump structure 360 over each under-bump-metallic layer 318a. The reflow process is carried out by irradiating the first solder portion 330 and the second solder portion 350 with infrared light or performing a forced convection process.

The present invention also provides a bump structure having a cross-section as shown in FIG. 3F. The bump structure 360 comprises a first solder portion 330, a second solder portion 350 and a conductive layer 340. The second solder portion 350 is disposed above the first solder portion 330. The conductive layer 340 is disposed between the first solder portion 330 and the second solder portion 350. The first solder portion 330 and the second solder portion 350 have a cylindrical or spherical shape so that the bump structure 360 has a roughly cylindrical shape. Hence, compared with a conventional bump structure with an equivalent volume, the bump structure of the present invention has a significant greater height. In addition, the first solder portion 330 and the second solder portion 350 can be fabricated using lead-tin alloy, tin-silver alloy or tin-silver-copper alloy, for example. In particular, there is no special restriction on the material composition and percentage composition of the constituents.

Furthermore, the conductive layer 340 comprises a first wetting layer 340a, a barrier layer 340b and a second wetting layer 340c. The first wetting layer 340a is disposed on the first solder portion 330. The barrier layer is disposed on the first wetting layer 340a. The second wetting layer 340c is disposed on the barrier layer 340b. The second solder portion 350 is disposed on the second wetting layer 340c. To enhance the bondability between the conductive layer 340 and the first solder portion 330, and the bondability of subsequently deposited solder material with the conductive layer, the first wetting layer 340a and the second wetting layer 340c are fabricated using copper, for example. The barrier layer 340b is fabricated using nickel-vanadium alloy, for example. The barrier layer 340b mainly serves as a barrier to the diffusion of mobile ions.

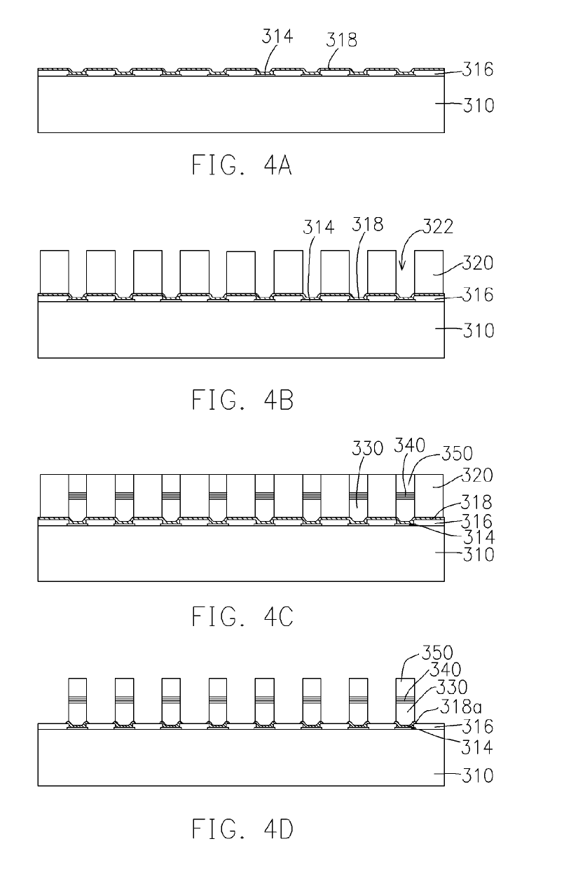

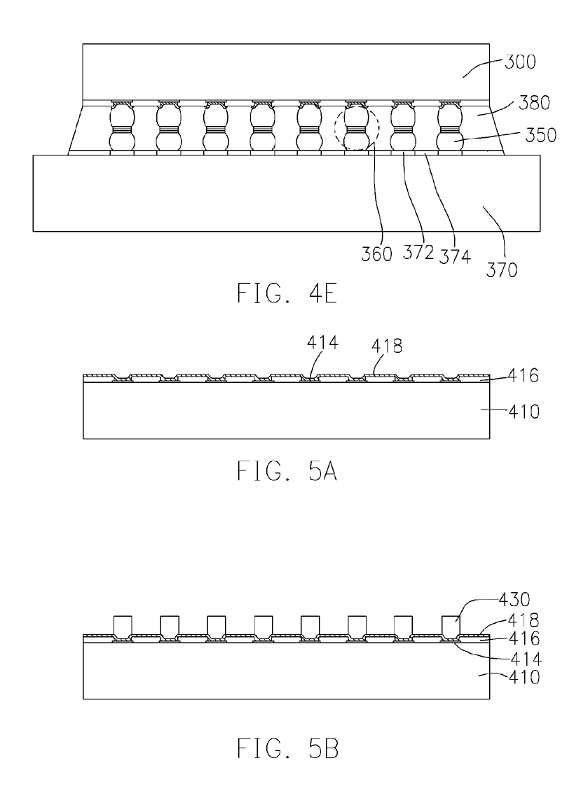

FIGS. 4A through 4E are schematic cross-sectional views showing the steps of fabricating a package structure according to one embodiment of the present invention. Since the steps shown in FIGS. 4A 4D are similar to the steps carried out in forming a bump structure as shown in FIGS. 3A through 3E, detailed descriptions are omitted. As shown in FIGS. 4D and 4E, the wafer 310 is sawed to form a plurality of chips 300. In the meantime, a package substrate 370 having a plurality of contacts 372 thereon is provided. Furthermore, the package substrate 370 has a solder mask layer 374 disposed on the surface outside the contacts 372. Thereafter, a reflow operation is carried out to join the second solder portions 350 of the chip 300 with the contacts 372 of the package substrate 370.

After joining the chip 300 and the package substrate 370 together, an underfill is filled into the space between the chip 300 and the package substrate 370 to protect the exposed portion of the bump structures 360 and disperse the stress.

It should be noted that the packaging process is not limited to forming the bump structures on the wafer first and joining to the package substrate thereafter. The bump structures may be formed on the package substrate first before joining with the wafer. Alternatively, the first solder portion, the second solder portion and the conductive layer of the bump structure are separately formed on the wafer and the package substrate before joining the wafer and the package substrate together.

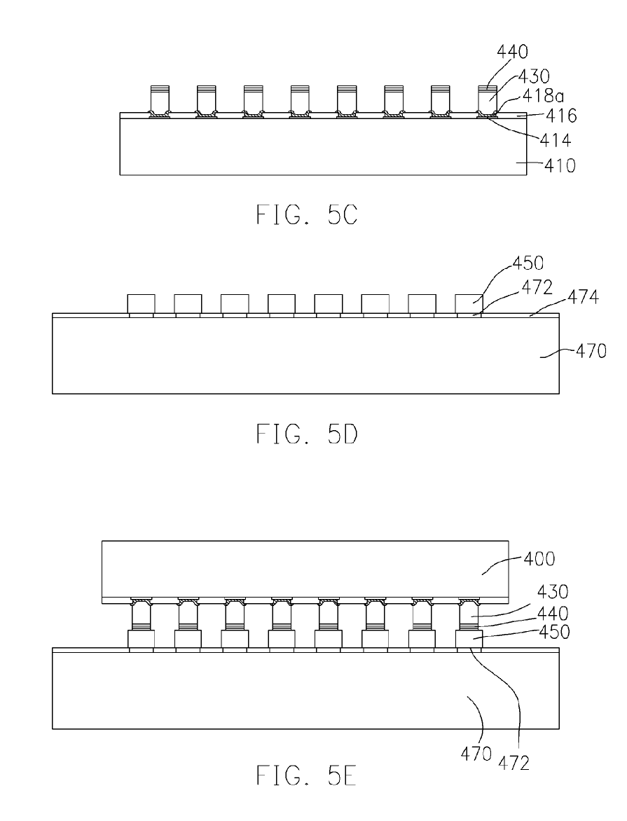

FIGS. 5A through 5F are schematic cross-sectional views showing the steps of fabricating a package structure according to another embodiment of the present invention. First, as shown in FIGS. 5A through 5C, a wafer 410 having a plurality of bonding pads 414 and a passivation layer 416 is provided, wherein the passivation layer 416 protects the wafer 410 and exposes the bonding pads 414. A metallic layer 418 is formed over the wafer 410 to cover the bonding pads 414 and the passivation layer 416, for example. Thereafter, an electroplating process is carried out to form a plurality of first solder portions 430 on the metallic layer 418 above the bonding pads 414. A sputtering, electroplating or evaporation process is carried out to form a conductive layer 440 over the first solder portions 430. The metallic layer 418 is patterned to form an under-bump-metallic layer 418a over each bonding pad 414.

As shown in FIG. 5D, a package substrate 470 having a plurality of contacts 472 thereon is provided. Furthermore, a solder mask layer 474 is also disposed on the package substrate 470 in areas outside the contacts 472. Thereafter, a printing method is used to form a plurality of second solder posts 450 on the contacts 472 of the package substrate 470.

As shown in FIGS. 5E and 5F, the wafer 410 in FIG. 5C is sawed to form a plurality of chips 400. Thereafter, a reflow process is carried out to join the conductive layers 440 on the chip 400 and the second solder posts 450 on the package substrate 470.

After joining the chip 400 and the package substrate 470 together, an underfill 480 is filled into the space between the chip 400 and the package substrate 470 for protecting the exposed portion of the bump structure 460 and dispersing the internal stress.

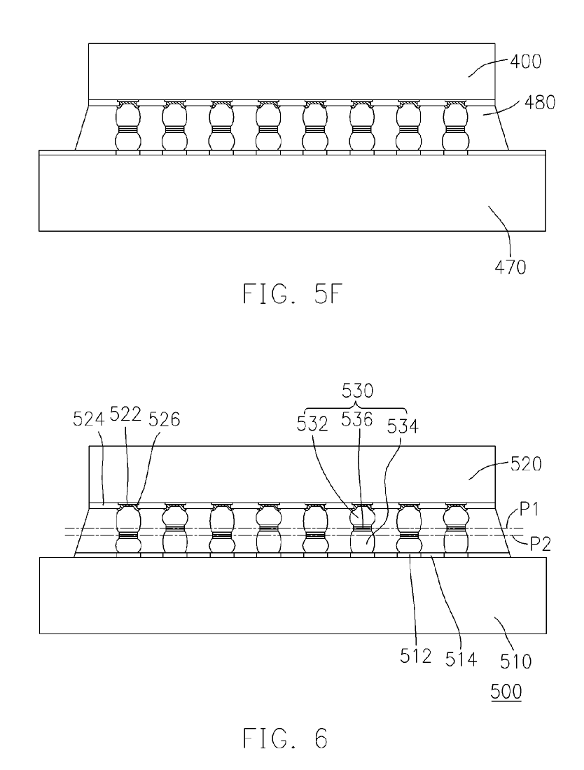

FIG. 6 is a schematic cross-sectional view of a package structure according to one embodiment of the present invention. As shown in FIG. 6, the package structure 500 comprises a package substrate 510, at least a chip 520 and a plurality of bump structures 530. The package structure 510 has a plurality of contacts 512 formed thereon. The chip 520 is disposed over the package substrate 510, for example. The chip 520 has a plurality of bonding pads 522 and a passivation layer 524, wherein the passivation layer 524 protects the chip 520 and exposes the bonding pads 522. Furthermore, an under-bump-metallic layer 526 is disposed over each bonding pad 522. The bumps structures 530 are disposed between the contacts 512 on the package substrate 510 and the under-bump-metallic layers 526 on the chip 520.

In addition, the bump structure 530 comprises a first solder portion 532, a second solder portion 534 and a conductive layer 536. The first solder portion 532 is disposed over the second solder portion 534 and the conductive layer 536 is disposed between the first solder portion 532 and the second solder portion 534. The first solder portion 532 and the second solder portion 534 have cylindrical or spherical shapes, for example. Furthermore, the first solder portion 532 and the second solder portion 534 are fabricated using lead-tin alloy, tin-silver alloy or tin-silver-copper alloy, for example. In general, there is no special restriction on the constituents and percentage of composition of the first solder portion 532 and the second solder portion 534. The conductive layer 536 has a structure and a material composition identical to the aforesaid bump structures and hence a detailed description is not repeated here. Moreover, a solder mask layer 514 may also be disposed on the package substrate 510 in areas outside the contacts 512.

It should be noted that some of the conductive layers 536 of the bump structure 530 are formed at a first height level P1 while the other conductive layers 536 are formed at a second height level P2. Those bump structures 530 having conductive layers 536 at the same height level are uniformly distributed within the package structure 500. By setting the conductive layers at different height levels, overall strength of the package structure 500 is improved. Obviously, the disposition of the height level of the conductive layer 536 can have many variations.

In summary, due to the isolation provided by the conductive layer, the first solder portion and the second solder portion are transformed into spherical bodies after a reflow process. Hence, overall height of the bump structures can be significantly increased. When the wafer is sawed into a plurality of chips and the chips are electrically connected to respective package substrate in a flip-chip bonding operation, the bump structures can withstand a higher level of thermal shear stress. In other words, the present invention produces bump structure with a greater height so that the electrical connection between the chip and the package substrate is more reliable.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A bumping process for forming a plurality of bumps on a plurality of contacts of a wafer or a package substrate, comprising:
forming a first solder portion on each contact; and
forming a conductive layer on each first solder portion.

2. The process of claim 1, further comprising a step of forming a metallic layer over the wafer, wherein the metallic layer at least covers the contacts.

3. The process of claim 1, wherein the step of forming the conductive layers comprises:
forming a first wetting layer over the first solder portion;
forming a barrier layer over the first wetting layer; and
forming a second wetting layer over the barrier layer.

4. The process of claim 1, further comprising a step of reflowing the first solder portions after the step of forming the conductive layers.

5. The process of claim 1, further comprising a step of forming a second solder portions over each conductive layer after the step of forming the conductive layers.

6. The process of claim 5, further comprising a step of reflowing the first solder portions and the second solder portions after the step of forming the second solder portions.

7. The process of claim 5, further comprising a step of forming a patterned photoresist layer over the wafer before the step of forming the first solder portions, such that the patterned photoresist layer has a plurality of openings that expose the metallic layer above the contacts.

8. A bump structure, comprising:
a first solder portion;
a second solder portion, disposed over the first solder portion; and
a conductive layer, disposed between the first solder portion and the second solder portion.

9. The bump structure of claim 8, wherein the conductive layer comprises:
a first wetting layer disposed on the first solder portion;
a barrier layer disposed on the first wetting layer; and
a second wetting layer disposed on the barrier layer.

10. The bump structure of claim 8, wherein a material of the first wetting layer comprises copper.

11. The bump structure of claim 8, wherein a material of the first barrier layer comprises nickel-vanadium alloy.

12. The bump structure of claim 8, wherein a material of the second wetting layer comprises copper.

13. The bump structure of claim 8, wherein the first solder portion has a cylindrical or spherical shape, and the second solder portion has a cylindrical or spherical shape.

14. The bump structure of claim 8, wherein a material of the first solder portion is identical to or different from a material of the second solder portion.

15. The bump structure of claim 8, wherein a material of the first solder portion is selected from a group consisting of lead-tin alloy, tin-silver alloy and tin-silver-copper alloy.

16. A packaging process, comprising:
providing a wafer having a plurality of bonding pads and a passivation layer for protecting the wafer and exposing the bonding pads;
forming a metallic layer over the wafer to cover at least the bonding pads;
forming a first solder portion over the metallic layer above the bonding pads;
forming a conductive layer over the first solder portions;
sawing the wafer to form a plurality of chips;
providing a package substrate having a plurality of contacts thereon;
forming a second solder portion over the contacts on the package substrate; and
joining the conductive layers on the chip with the second solder portions on the package substrate.

17. The packaging process of claim 16, wherein the step of forming the conductive layer comprises:
forming a first wetting layer over the first solder portion;
forming a barrier layer over the first wetting layer; and
forming a second wetting layer over the barrier layer.

18. The packaging process of claim 16, wherein the step of joining the second solder portion with the conductive layer comprises performing a reflow process.

19. The packaging process of claim 16, further comprising a step of forming a patterned photoresist layer over the wafer before the step of forming the first solder portion such that the patterned photoresist layer has a plurality of openings that expose the metallic layer above the bonding pads.

20. A packaging process, comprising:
providing a wafer having a plurality of bonding pads and a passivation layer for protecting the wafer and exposing the bonding pads;
forming a metallic layer over the wafer to cover at least the bonding pads;
forming a first solder portion over the metallic layer above the bonding pads;
forming a conductive layer over the first solder portions;
forming a second solder portion over each conductive layer;
sawing the wafer to form a plurality of chips;
providing a package substrate having a plurality of contacts thereon; and
joining the second solder portions of the chips with the contacts on the package substrate.

21. The packaging process of claim 20, wherein the step of forming the conductive layer comprises:
forming a first wetting layer over the first solder portion;
forming a barrier layer over the first wetting layer; and
forming a second wetting layer over the barrier layer.

22. The packaging process of claim 20, wherein the step of joining the second solder portion with the contacts comprises performing a reflow process.

23. The packaging process of claim 20, further comprising a step of forming a patterned photoresist layer over the wafer before the step of forming the first solder portion such that the patterned photoresist layer has a plurality of openings that expose the metallic layer above the bonding pads.

24. A package structure, comprising:
a package substrate having a plurality of contacts thereon;
a chip, disposed over the package substrate, wherein the chip has a plurality of bonding pads and a passivation layer, the passivation layer protects the chip and exposes the bonding pads and each bonding pad has an under-bump-metallic layer disposed thereon;
a plurality of bump structures, disposed between the contacts on the package substrate and the under-bump-metallic layers on the chip, wherein each bump structure further comprises:
a first solder portion;
a second solder portion, disposed over the first solder portion; and
a conductive layer, disposed between the first solder portion and the second solder portion.

25. The package structure of claim 24, wherein the conductive layer comprises:
a first wetting layer, disposed over the first solder portion;
a barrier layer, disposed over the first wetting layer; and
a second wetting layer, disposed over the barrier layer.

26. The package structure of claim 24, wherein the first solder portion has a cylindrical or spherical shape, and the second solder portion has a cylindrical or spherical shape.

27. The package structure of claim 24, wherein a material of the first solder portion is identical to or different from a material of the second solder portion.

28. The package structure of claim 24, wherein the package structure comprises a solder mask layer disposed on the package substrate to cover an area outside the contacts.

29. The package structure of claim 24, wherein some of the conductive layers within the bump structures are disposed at a first height level while the other conductive layers are disposed at a second height level.
